(19) United States
(12) Patent Application Publication
(10) Pub. No.: US 2026/0323957 A1
(43) Pub. Date: Oct. 15, 2026

(54) INTEGRATED CHIP AND METHOD OF MANUFACTURING THE SAME

(71) Applicant: Taiwan Semiconductor Manufacturing Company, Ltd., Hsinchu (TW)

(72) Inventors: Fu-Ting Sung, Yangmei City (TW); Hsia-Wei Chen, Taipei City (TW); Yen-Chang Lin, Taichung City (TW); Yu-Wen Liao, New Taipei City (TW); Wen-Ting Chu, Kaohsiung City (TW)

(21) Appl. No.: 19/306,149

(22) Filed: Aug. 21, 2025

Related U.S. Application Data
(60) Provisional application No. 63/788,293, filed on Apr. 14, 2025.

(51) Int. Cl. H10B 63/00

(52) U.S. Cl. CPC H10B 63/30

(57) ABSTRACT

An integrated chip includes a barrier layer including a first conductive material over a semiconductor substrate. The integrated chip includes a lower electrode layer including a second conductive material, different than the first conductive material, over the barrier layer. The integrated chip includes a dielectric layer over the lower electrode layer. The integrated chip includes an upper electrode layer over the dielectric layer. The integrated chip includes an encapsulation layer including a first dielectric material encapsulating the upper electrode layer, the dielectric layer, the lower electrode layer, and the barrier layer. The integrated chip includes a spacer layer including a second dielectric material, different than the first dielectric material, on an upper surface of the barrier layer. The encapsulation layer is spaced from sidewalls of the lower electrode layer, sidewalls of the dielectric layer, and sidewalls of the upper electrode layer by the spacer layer.

### REFERENCE TO RELATED APPLICATION

This Application claims the benefit of U.S. Provisional Application No. 63/788,293, filed on Apr. 14, 2025, the contents of which are hereby incorporated by reference in their entirety.

### BACKGROUND

Many modern electronic devices contain electronic memory configured to store data. Electronic memory may be volatile or non-volatile. Volatile memory stores data while it is powered, while non-volatile memory is able to keep data when power is off. Resistive random-access memory (RRAM) is one promising candidate for next generation non-volatile memory due to its simple structure and compatibility with complementary metal-oxide semiconductor (CMOS) processes.

### BRIEF DESCRIPTION OF THE DRAWINGS

Aspects of the present disclosure are best understood from the following detailed description when read with the accompanying figures. The figures are drawn to clearly illustrate relevant aspects of the embodiments. The figures may illustrate relationships between various structures and/or elements within the embodiments. It is noted that the figures are not necessarily drawn to scale. In some instances, the dimensions of the various features may be arbitrarily increased or reduced for clarity of discussion.

FIG. 1 illustrates a cross-sectional view of some embodiments of a memory cell comprising a spacer layer covering sidewalls of an upper electrode layer, sidewalls of a data storage layer, and sidewalls of a lower electrode layer.

FIG. 2 illustrates a cross-sectional view of some embodiments of the memory cell in which a capping layer is between the upper electrode layer and the data storage layer, and the spacer layer covers sidewalls of the capping layer.

FIG. 3 illustrates a top view of some embodiments of the memory cell.

FIG. 4 illustrates a cross-sectional view of some embodiments of an integrated chip comprising the memory cell.

FIG. 5 illustrates a cross-sectional view of some embodiments of the memory cell.

FIG. 6 illustrates a cross-sectional view of some embodiments of the integrated chip in which the integrated chip includes a memory region and a logic region.

FIG. 7 illustrates a cross-sectional view of some embodiments of the integrated chip in which a plurality of memory cells are laterally spaced apart in the memory region.

FIG. 8 illustrates a cross-sectional view of some embodiments of the memory cell.

FIG. 9 and FIG. 10 illustrate cross-sectional views of some embodiments of the memory cell in which two spacer layers surround the memory cell.

FIG. 11 and FIG. 12 illustrate cross-sectional views of some embodiments of the memory cell in which the lower electrode layer is laterally recessed at sidewalls of the lower electrode layer.

FIG. 13 and FIG. 14 illustrate cross-sectional views of some embodiments of the memory cell in which the lower electrode layer is substantially devoid of the lateral recesses at the sidewalls of the lower electrode layer.

FIGS. 15-25 illustrate cross-sectional views of some embodiments of a method of forming the integrated chip comprising the memory cell.

FIGS. 26-30 illustrate cross-sectional views of some embodiments of a method of forming the memory cell.

FIGS. 31-38 illustrate cross-sectional views of some embodiments of a method of forming the memory cell.

FIG. 39 illustrates a flow diagram of some embodiments of a method of forming the integrated chip comprising the memory cell.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In some embodiments, the terms “approximately” and/or “about” can be interpreted as meaning +/−10% or +/−5%, while in other embodiments, the terms “approximately” and/or “about” can be interpreted as meaning within the normal fabrication tolerances of a given fab manufacturing flow.

An integrated chip includes a transistor over and/or along a semiconductor substrate. A conductive interconnect is over and coupled to the transistor. A memory cell is over the conductive interconnect and coupled to the transistor by the conductive interconnect. The memory cell includes a lower electrode layer coupled to the conductive interconnect, a data storage layer (e.g., a memory layer) on the lower electrode layer, and an upper electrode layer on the data storage layer. The data storage layer can be put in a first state (e.g., a high resistive state) to store a first logic value (e.g., 0) in the memory cell. The data storage layer can be put in a second state (e.g., a low resistive state) to store a second logic value (e.g., 1) in the memory cell.

An encapsulation layer extends over the upper electrode layer and along sidewalls of the upper electrode layer, the data storage layer, and the lower electrode layer. In some cases, the encapsulation layer comprises a dielectric material which comprises oxygen (e.g., silicon oxide). Consequently, in some cases, portions of the upper electrode layer and/or the lower electrode layer can be oxidized when forming the encapsulation layer. This oxidization can reduce a performance and/or a reliability of the memory cell.

In various embodiments of the present disclosure, a spacer layer is formed on sidewalls of the lower electrode layer, sidewalls of the data storage layer, and sidewalls of the upper electrode layer before the encapsulation layer is formed to protect the upper electrode layer and the lower electrode layer from oxidation during the formation of the encapsulation layer. The spacer layer may reduce oxidation of the upper electrode layer and/or the lower electrode layer during the formation of the encapsulation layer. As a result, a performance and/or a reliability of the memory cell may be improved.

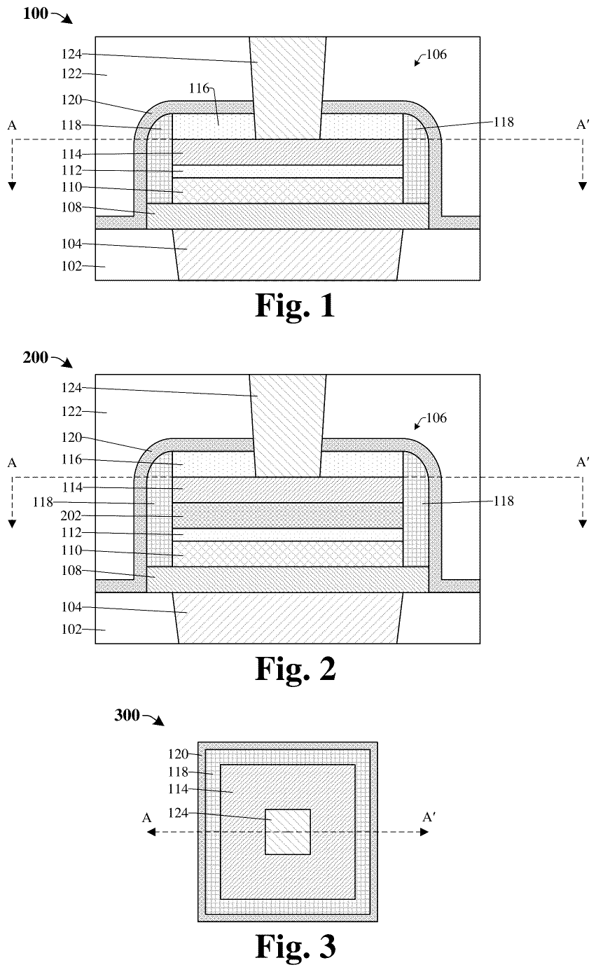

FIG. 1 illustrates a cross-sectional view 100 of some embodiments of a memory cell 106 comprising a spacer layer 118 covering sidewalls of an upper electrode layer 114, sidewalls of a data storage layer 112, and sidewalls of a lower electrode layer 110. FIG. 2 illustrates a cross-sectional view 200 of some embodiments of the memory cell 106 in which a capping layer 202 is between the upper electrode layer 114 and the data storage layer 112, and the spacer layer 118 covers sidewalls of the capping layer 202. FIG. 3 illustrates a top view 300 of some embodiments of the memory cell 106. In some embodiments, section line A-A′ of FIG. 3 corresponds to section line A-A′ of FIG. 1 and/or FIG. 2.

The memory cell 106 is over a conductive interconnect 104 (e.g., a conductive line) and a dielectric layer 102. The memory cell 106 comprises a barrier layer 108, a lower electrode layer 110, a data storage layer 112 (e.g., a memory layer), an upper electrode layer 114, a hard mask layer 116, and the spacer layer 118. The barrier layer 108 is on a top surface of dielectric layer 102, on a top surface of conductive interconnect 104, and coupled to conductive interconnect 104. The lower electrode layer 110 is on a top surface of the barrier layer 108 and coupled to conductive interconnect 104 by the barrier layer 108. The data storage layer 112 is on a top surface of the lower electrode layer 110. The upper electrode layer 114 is on a top surface of the data storage layer 112. The hard mask layer 116 is on a top surface of the upper electrode layer 114. A dielectric layer 122 is over the memory cell 106. A conductive interconnect 124 (e.g., a conductive via) extends through dielectric layer 122 and the hard mask layer 116 to the upper electrode layer 114.

Data can be stored by the memory cell 106 by adjusting the resistance of the data storage layer 112, which can be achieved by applying voltage across the data storage layer 112. For example, a first voltage can be applied across the data storage layer 112 to put the data storage layer 112 in a first state (e.g., a high resistive state) to store a first logic value (e.g., 0) in the memory cell 106. A second voltage, different than the first voltage, can be applied across the data storage layer 112 to put the data storage layer 112 in a second state (e.g., a low resistive state) to store a second logic value (e.g., 1) in the memory cell 106.

The spacer layer 118 is on the top surface of the barrier layer 108, sidewalls of the lower electrode layer 110, sidewalls of the data storage layer 112, sidewalls of the upper electrode layer 114, and sidewalls of the hard mask layer 116. In some embodiments, the spacer layer 118 laterally surrounds the lower electrode layer 110, the data storage layer 112, the upper electrode layer 114, and the hard mask layer 116 in a ring-shaped closed path (e.g., as illustrated in FIG. 3).

An encapsulation layer 120 encapsulates the spacer layer 118, the hard mask layer 116, the upper electrode layer 114, the data storage layer 112, the lower electrode layer 110, and the barrier layer 108. The encapsulation layer 120 is spaced from the sidewalls of the lower electrode layer 110, the sidewalls of the data storage layer 112, and the sidewalls of the upper electrode layer 114 by the spacer layer 118. Thus, the spacer layer 118 can protect the lower electrode layer 110 and the upper electrode layer 114 from being oxidized during the formation of the encapsulation layer 120.

By reducing the oxidation of the lower electrode layer 110 and the upper electrode layer 114, a performance and/or a reliability of the memory cell 106 can be improved. For example, the effective area of the memory cell 106 (corresponding to a capacitance of the memory cell 106) can be increased, a forming voltage (e.g., the voltage for writing the memory cell) can be reduced, a bit error rate can be reduced, a set/reset shot count (e.g., the number of voltage pulses applied to set/reset the memory cell) can be reduced, a set/reset shot count stability can be improved, a set/reset speed can be improved, a natural yield (e.g., amount of memory cells that function properly without repair) can improved, a repair rate (e.g., amount of memory cells that function properly after repair) can be improved, and/or a structural integrity of the memory cell 106 may be improved.

The spacer layer 118 comprises an oxygen-free dielectric material or a low-oxygen dielectric material to further reduce oxidization of the upper electrode layer 114, the capping layer 202, and the lower electrode layer 110. For example, in some embodiments, the spacer layer 118 comprises a lower atomic percentage of oxygen than the encapsulation layer 120. In some embodiments, the atomic percentage of oxygen in the spacer layer 118 is less than 20%, less than 15%, or some other suitable value. In some embodiments, the spacer layer 118 is substantially devoid of oxygen (e.g., the atomic percentage of oxygen in the spacer layer 118 is less than 4%, less than 2%, less than 1%, less than 0.5%, or some other suitable value). In some embodiments, the oxygen-free dielectric material is or comprises silicon nitride, silicon carbide, silicon carbonitride, or some other suitable material. In some embodiments, the low-oxygen dielectric material is or comprises silicon oxynitride, silicon oxycarbide, silicon oxycarbonitride, or some other suitable material.

In some embodiments, the memory cell 106 is a resistive random access memory (RRAM) cell in which the data storage layer 112 comprises a high-k dielectric material. In such embodiments, a first voltage can be applied across the data storage layer to form conductive filaments with oxygen vacancies within the data storage layer 112 to reduce the resistance of the data storage layer 112, thus storing the second logic value (e.g., “1”) in the memory cell 106. Further, a second voltage can be applied across the data storage layer 112 to break conductive filaments within the data storage layer 112 to increase the resistance of the data storage layer 112, thus storing the first logic value (e.g., “0”) in the memory cell 106. In some embodiments in which the memory cell is a RRAM cell, the memory cell 106 further comprises a capping layer 202 between the data storage layer 112 and the upper electrode layer 114, as illustrated in FIG. 2. The capping layer 202 may help to provide the oxygen vacancies (which form the conductive filaments) to the data storage layer 112.

In some other embodiments, the memory cell 106 is a phase change random access memory (PCRAM) cell in which the data storage layer 112 comprises a chalcogenide material. In some other embodiments, the memory cell is a magnetoresistive random access memory (MRAM) cell in which the electrode layers 110, 114 comprise ferromagnetic materials and the data storage layer 112 comprises a tunnel barrier dielectric material. In some other embodiments, the memory cell 106 is a ferroelectric random access memory (FeRAM) cell in which the data storage layer 112 comprises a ferroelectric material.

The barrier layer 108 comprises a first conductive material. In some embodiments, the barrier layer 108 comprises tantalum, titanium, ruthenium, aluminum, cobalt, molybdenum, rhodium, tantalum nitride, titanium nitride, ruthenium nitride, aluminum nitride, cobalt nitride, molybdenum nitride, rhodium nitride, tungsten nitride, manganese nitride, nickel nitride, tin nitride, magnesium nitride or some other suitable material. In some embodiments, the thickness of the barrier layer 108 ranges from about 5 angstroms to about 140 angstroms, from about 10 angstroms to about 130 angstroms, from about 20 angstroms to about 100 angstroms, or some other suitable thickness.

The lower electrode layer 110 comprises a second conductive material different than the first conductive material. In some embodiments, the lower electrode layer 110 comprises ruthenium, rhodium, palladium, osmium, iridium, platinum, gold, silver, copper, aluminum, tungsten, tantalum, titanium, an alloy of any of ruthenium, rhodium, palladium, osmium, iridium, platinum, gold, silver, copper, aluminum, tungsten, tantalum, and titanium, a nitride of any of ruthenium, rhodium, palladium, osmium, iridium, platinum, gold, silver, copper, aluminum, tungsten, tantalum, and titanium, or some other suitable material. In some embodiments, the thickness of the lower electrode layer 110 ranges from about 20 angstroms to about 200 angstroms, from about 75 angstroms to about 200 angstroms, from about 100 angstroms to about 200 angstroms, or some other suitable thickness.

In some embodiments, the data storage layer 112 comprises a high-k dielectric material such as, for example, hafnium oxide, zirconium oxide, lanthanum oxide, gadolinium oxide, yttrium oxide, aluminum oxide, some other high-k dielectric material, or some other suitable material. In some embodiments, the thickness of the data storage layer 112 ranges from about 10 angstroms to about 100 angstroms, from about 10 angstroms to about 90 angstroms, from about 10 angstroms to about 80 angstroms, or some other suitable thickness.

The capping layer 202 comprises a third conductive material. In some embodiments, the capping layer 202 comprises titanium, hafnium, platinum, aluminum, tantalum, zirconium, nickel, iridium, or some other suitable material. In some embodiments, the thickness of the capping layer 202 ranges from about 25 angstroms to about 200 angstroms, from about 50 angstroms to about 200 angstroms, from about 75 angstroms to about 200 angstroms, or some other suitable thickness.

The upper electrode layer 114 comprises a fourth conductive material different than the third conductive material. In some embodiments, the upper electrode layer 114 comprises ruthenium, rhodium, palladium, osmium, iridium, platinum, gold, silver, copper, aluminum, tungsten, tantalum, titanium, an alloy of any of ruthenium, rhodium, palladium, osmium, iridium, platinum, gold, silver, copper, aluminum, tungsten, tantalum, and titanium, a nitride of any of ruthenium, rhodium, palladium, osmium, iridium, platinum, gold, silver, copper, aluminum, tungsten, tantalum, and titanium, or some other suitable material. In some embodiments, the thickness of the upper electrode layer 114 ranges from about 25 angstroms to about 200 angstroms, from about 50 angstroms to about 200 angstroms, from about 75 angstroms to about 200 angstroms, or some other suitable thickness.

In some embodiments, the hard mask layer 116 comprises silicon nitride, silicon oxynitride, silicon carbonitride, silicon oxycarbonitride, some metal nitride, or some other suitable material.

The encapsulation layer 120 comprises a different dielectric material than the spacer layer 118. In some embodiments, the encapsulation layer 120 comprises a tetraethyl orthosilicate (TEOS) silicon dioxide or some other suitable material. In some embodiments, dielectric layer 102 and/or dielectric layer 122 comprise a low-k dielectric material, an extremely low-k dielectric material (e.g., having a dielectric constant k of less than 2.5), or some other suitable material. In some embodiments, conductive interconnect 104 and/or conductive interconnect 124 comprise copper, aluminum, tungsten, titanium, tantalum, or some other suitable material.

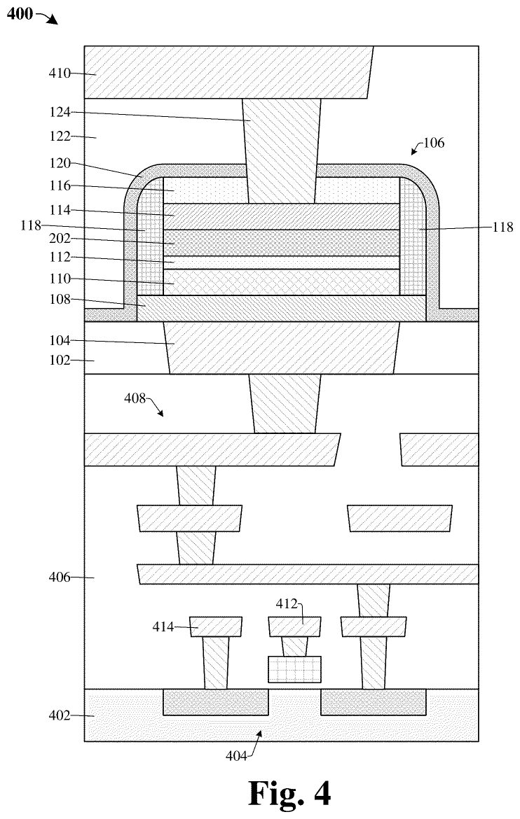

FIG. 4 illustrates a cross-sectional view 400 of some embodiments of an integrated chip comprising the memory cell 106.

A transistor 404 is disposed over and/or along a semiconductor substrate 402. The transistor 404 includes a first source/drain, a second source/drain, and a gate structure. Source/drain(s) may refer to a source or a drain, individually or collectively dependent upon the context. In some embodiments, the gate structure of transistor 404 (and/or conductive interconnect 412 coupled to the gate structure of transistor 404) forms a word line of a memory array which includes memory cell 106.

A dielectric structure 406 comprising a plurality of dielectric layers is over the semiconductor substrate 402. An interconnect structure 408 comprising a plurality of conductive interconnects (e.g., conductive lines, conductive vias, conductive pads, conductive contacts, etc.) is within the dielectric structure 406. In some embodiments, conductive interconnect 414 is coupled to the first source/drain of transistor 404 and forms a source line of the memory array.

Dielectric layer 102 is over dielectric structure 406. Conductive interconnect 104 is over interconnect structure 408 and coupled to the second source/drain of transistor 404 by conductive interconnect structure 408. A plurality of conductive interconnects, including a conductive interconnect 410, are over and coupled to conductive interconnect 124. In some embodiments, conductive interconnect 410 forms a bit line of the memory array.

In some embodiments, transistor 404 is a metal-oxide-semiconductor field-effect transistor (MOSFET), a junction field-effect transistor (JFET), a bipolar junction transistor (BJT), a fin field-effect transistor (Fin FET), a gate-all around field-effect transistor (GAA FET), some other suitable device.

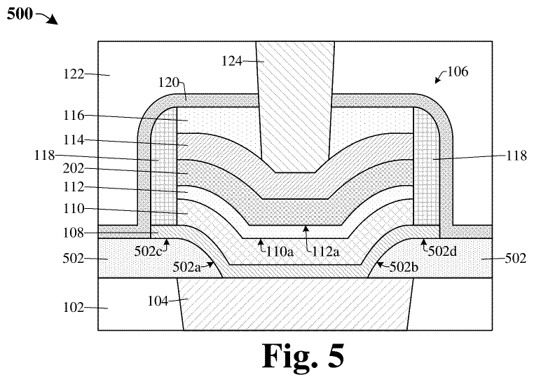

FIG. 5 illustrates a cross-sectional view 500 of some embodiments of the memory cell 106 in which a diffusion blocking dielectric layer 502 is between the encapsulation layer 120 and dielectric layer 102.

The diffusion blocking dielectric layer 502 is on dielectric layer 102 and conductive interconnect 104. The diffusion blocking dielectric layer 502 may help prevent diffusion of atoms from conductive interconnect 104 into overlying layers. The diffusion blocking dielectric layer 502 has an opening therein directly over conductive interconnect 104 where the barrier layer 108 contacts conductive interconnect 104. The opening is delimited by sidewalls 502a, 502b of the diffusion blocking dielectric layer 502.

The barrier layer 108 conformally overlies conductive interconnect 104 and the diffusion blocking dielectric layer 502. For example, the barrier layer 108 is on a first upper surface 502c, a second upper surface 502d, sidewall 502a, and sidewall 502b of the diffusion blocking dielectric layer 502. The barrier layer 108 extends on an upper surface of conductive interconnect 104 from sidewall 502a to sidewall 502b of the diffusion blocking dielectric layer 502.

The lower electrode layer 110, the data storage layer 112, the capping layer 202, and the upper electrode layer 114 conformally overlie the barrier layer 108 in a stack and thus have similar shapes. For example, the lower electrode layer 110 is on a first sidewall (not labeled) of the barrier layer 108, a second sidewall (not labeled) of the barrier layer 108, and an upper surface (not labeled) of the barrier layer 108 from the first sidewall to the second sidewall of the barrier layer 108. The hard mask layer 116 conforms to the upper electrode layer 114 but has a substantially planar upper surface.

The spacer layer 118 is on a first upper surface of the barrier layer 108 (e.g., on a first raised portion of the barrier layer 108 that overlies a first portion of the diffusion blocking dielectric layer 502) and a second upper surface of the barrier layer 108 (e.g., on a second raised portion of the barrier layer 108 that overlies a second portion of the diffusion blocking dielectric layer 502). In some embodiments, a bottommost surface of the spacer layer 118 is above an upper surface 110a of the lower electrode layer 110. In some embodiments, the bottommost surface of the spacer layer 118 is above an upper surface 112a of the data storage layer 112.

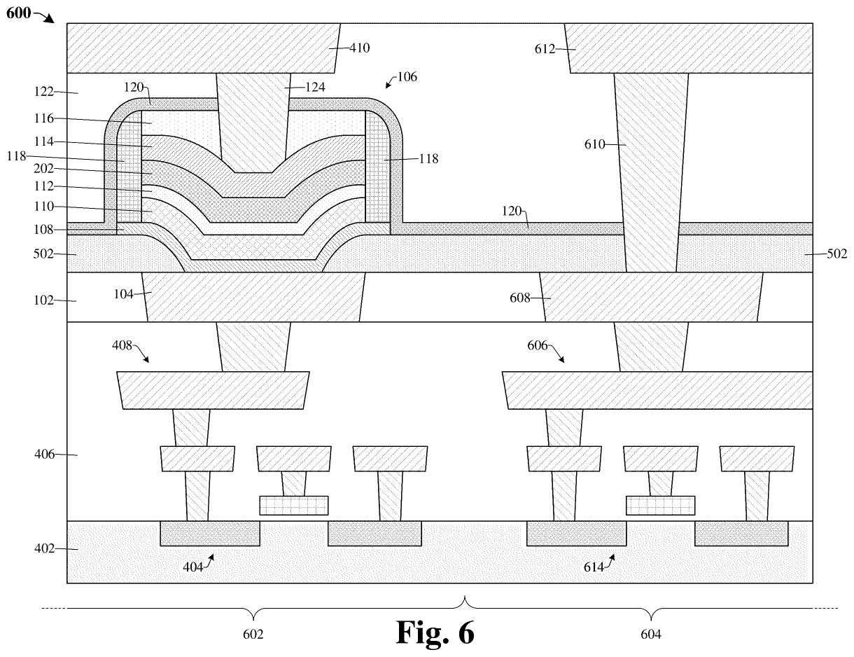

FIG. 6 illustrates a cross-sectional view 600 of some embodiments of the integrated chip in which the integrated chip includes a memory region 602 and a logic region 604.

The memory cell 106 is within the memory region 602 of the integrated chip. In some embodiments, the logic region 604 neighbors the memory region 602. Transistors in the logic region 604 are laterally spaced from transistors in the memory region 602. For example, transistor 614 is laterally spaced from transistor 404. Similarly, conductive interconnects in the logic region 604 are laterally spaced from the memory cell 106 and from conductive interconnects in the memory region 602. For example, conductive interconnect structure 606 is laterally spaced from conductive interconnect structure 408, conductive line 608 is laterally spaced from conductive line 104, conductive via 610 is laterally spaced from conductive via 124 and memory cell 106, and conductive line 612 is laterally spaced from conductive line 410. Conductive via 610 extends from conductive line 612 through dielectric layer 122, through the encapsulation layer 120, and through the diffusion blocking dielectric layer 502 to conductive line 608. In some embodiments, a top surface of conductive via 124 and a top surface of conductive via 610 are approximately vertically aligned. A bottom surface of conductive via 610 is below a bottom surface of conductive via 124.

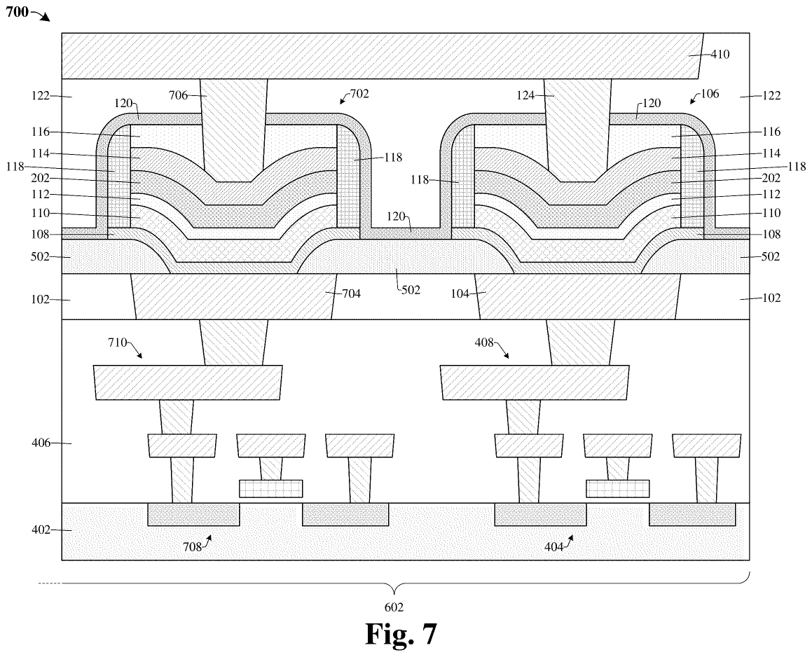

FIG. 7 illustrates a cross-sectional view 700 of some embodiments of the integrated chip in which a plurality of memory cells are laterally spaced apart in the memory region 602.

For example, a memory cell 702 is in the memory region 602 and laterally spaced from memory cell 106. Memory cell 106 is formed by (e.g., comprises) a first portion of barrier layer 108 (e.g., a first barrier structure), a first portion of lower electrode layer 110 (e.g., a first lower electrode), a first portion of data storage layer 112 (e.g., a first data storage structure), a first portion of capping layer 202 (e.g., a first capping structure), a first portion of upper electrode layer 114 (e.g., a first upper electrode), a first portion of hard mask layer 116 (e.g., a first hard mask structure), and a first portion of spacer layer 118 (e.g., a first spacer structure). Memory cell 702 is formed by (e.g., comprises) a second portion of barrier layer 108 (e.g., a second barrier structure), a second portion of lower electrode layer 110 (e.g., a second lower electrode), a second portion of data storage layer 112 (e.g., a second data storage structure), a second portion of capping layer 202 (e.g., a second capping structure), a second portion of upper electrode layer 114 (e.g., a second upper electrode), a second portion of hard mask layer 116 (e.g., a second hard mask structure), and a second portion of spacer layer 118 (e.g., a second spacer structure). The encapsulation layer 120 conformally overlies memory cell 106, memory cell 702, and the diffusion blocking dielectric layer 502 between the memory cells 106, 702.

Memory cell 702 is over and coupled to a conductive line 704, which is over and coupled to a transistor 708 by a conductive interconnect structure 710. A conductive via 706 is over and coupled to memory cell 702. In some embodiments, conductive line 410 is over and coupled to both conductive via 124 and conductive via 706 (e.g., conductive line 410 is a shared bit line). In some other embodiments, a separate conductive line (not shown) is over and coupled to conductive via 706 and isolated from conductive line 410.

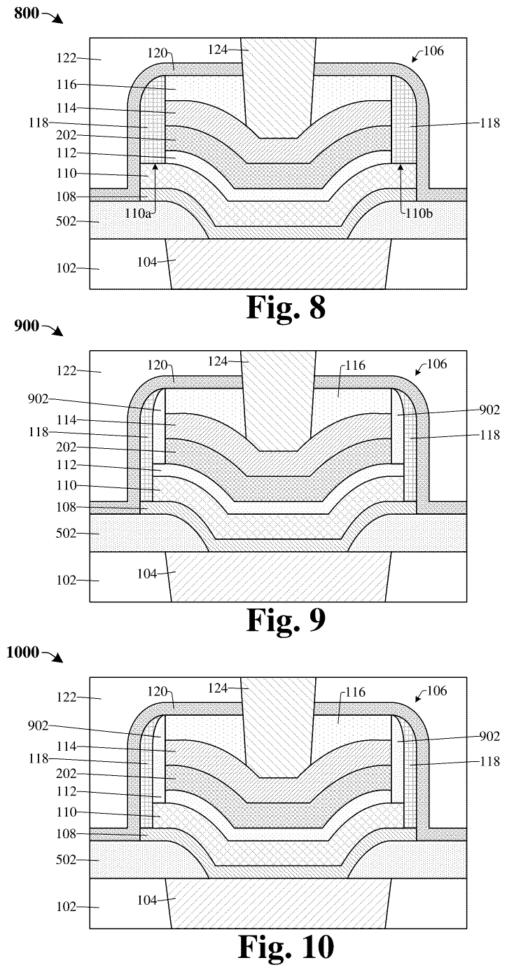

FIG. 8 illustrates a cross-sectional view 800 of some embodiments of the memory cell 106 in which the lower electrode layer 110 is between the spacer layer 118 and the barrier layer 108.

The spacer layer 118 is on upper surfaces 110a, 110b of the lower electrode layer 110. The encapsulation layer 120 covers sidewalls of the lower electrode layer 110. The spacer layer 118 is formed on the upper surfaces 110a, 110b of the lower electrode layer 110 before the lower electrode layer 110 is etched. Thus, the spacer layer 118 can protect the upper electrode layer 114 and the capping layer 202 from oxidization during the etching of the lower electrode layer 110 and subsequent processes. Thus, a performance and/or a reliability of the memory cell 106 may be improved.

FIG. 9 illustrates a cross-sectional view 900 of some embodiments of the memory cell 106 in which two spacer layers protect the memory cell 106. FIG. 10 illustrates a cross-sectional view 1000 of some other embodiments of the memory cell 106 in which two spacer layers protect the memory cell 106.

Spacer layer 902 is between spacer layer 118 and layers 202, 114, 116. In some embodiments (e.g., as illustrated in FIG. 9), spacer layer 902 is on upper surfaces of the data storage layer 112 and covers sidewalls of hard mask layer 116, sidewalls of upper electrode layer 114, and sidewalls of capping layer 202. In some embodiments (e.g., as illustrated in FIG. 10), spacer layer 902 is on upper surfaces of the lower electrode layer 110 and further covers sidewalls of data storage layer 112.

In some embodiments (e.g., as illustrated in FIG. 9), spacer layer 902 can protect the upper electrode layer 114 and the capping layer 202 from oxidization during the etching of the data storage layer 112 and the lower electrode layer 110, and spacer layer 118 can protect the data storage layer 112 and the lower electrode layer 110 during the deposition of the encapsulation layer 120. In some embodiments (e.g., as illustrated in FIG. 10), spacer layer 902 can protect the upper electrode layer 114, the capping layer 202, and the data storage layer 112 from oxidization during the etching of the lower electrode layer 110, and spacer layer 118 can protect the lower electrode layer 110 during the deposition of the encapsulation layer 120. Thus, a performance and/or a reliability of the memory cell 106 may be improved.

In some embodiments, spacer layer 902 and spacer layer 118 comprise a same dielectric material. In some other embodiments, spacer layer 118 comprises a first dielectric material and spacer layer 902 comprises a second dielectric material different than the first dielectric material.

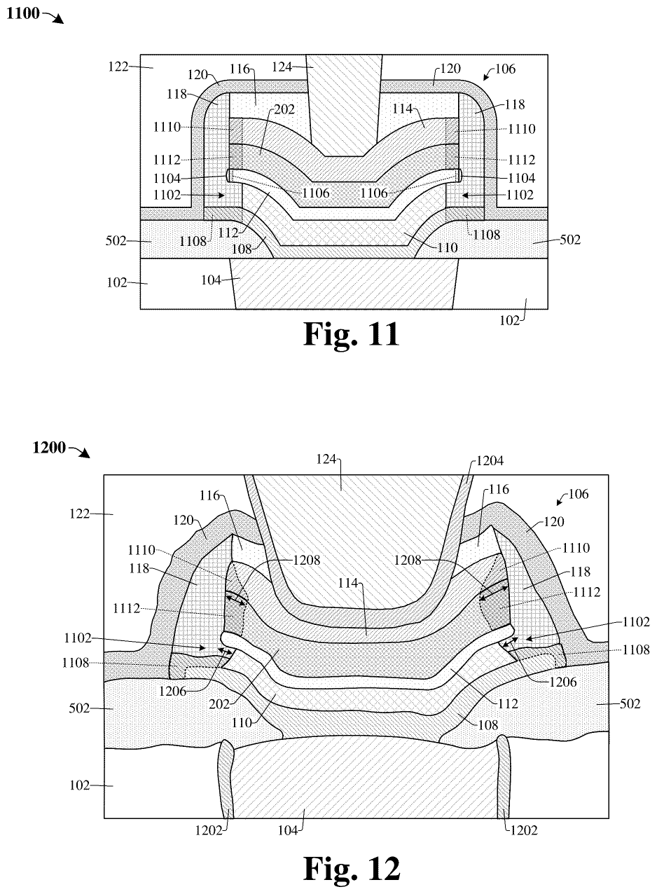

FIG. 11 and FIG. 12 illustrate cross-sectional views 1100, 1200, respectively, of some embodiments of the memory cell 106 in which the lower electrode layer 110 is laterally recessed at sidewalls of the lower electrode layer 110.

The lower electrode layer 110 is “undercut” (e.g., laterally recessed) along sidewalls of the lower electrode layer 110 (as illustrated at 1102) so that the sidewalls of the lower electrode layer 110 are substantially offset from sidewalls of the data storage layer 112, sidewalls of the capping layer 202, sidewalls of the upper electrode layer 114, and sidewalls of the hard mask layer 116. The spacer layer 118 extends under a portion of the data storage layer 112 where the lower electrode layer 110 is laterally recessed. The lateral recessing of the lower electrode layer 110 may occur during the etching of the lower electrode layer 110. In some embodiments, the width 1206 of the undercut (e.g., the lateral offset between the sidewalls of the lower electrode layer 110 and the sidewalls of the data storage layer 112) ranges from about 10 angstroms to about 100 angstroms, from about 20 angstroms to about 100 angstroms, from about 50 angstroms to about 100 angstroms, or some other range.

In some embodiments, material removed from the lower electrode layer 110 (at the lateral recess “undercut”) is deposited (e.g., “resputtered”) on sidewalls of the data storage layer 112 during the etching of the lower electrode layer 110. In some embodiments, this material forms a layer 1104 (e.g., a metal oxide layer) on the sidewalls of the data storage layer 112. In some embodiments, this lower electrode material may diffuse into the data storage layer 112 through the sidewalls of the data storage layer 112 so that edge portions 1106 of the data storage layer 112 further comprise the lower electrode material (e.g., atoms of the lower electrode material) in the dielectric material of the data storage layer 112.

In some embodiments, in addition to the conductive material of the barrier layer 108, edge portions 1108 of the barrier layer 108 further comprise atoms from one or more etching gases (e.g., edge portions 1108 of the barrier layer 108 further comprise one or more of oxygen, fluorine, chlorine, bromine, and iodine) used in the etching of the lower electrode layer 110. In some embodiments, these edge portions 1108 of the barrier layer 108 have increased thickness (e.g., the thickness of edge portions 1108 is greater than a thickness of a central portion of the barrier layer 108 that extends between the edge portions 1108) due to the added materials. In some embodiments, the edge portions 1108 of the barrier layer 108 cover portions of the sidewalls of the lower electrode layer 110 due to the increased thickness of the barrier layer 108 at edge portions 1108, as illustrated in FIG. 12. The spacer layer 118 contacts the barrier layer 108 at the edge portions 1108 of the barrier layer 108.

In some embodiments, edge portions 1110 (e.g., sidewall regions) of the upper electrode layer 114 and edge portions 1112 of the capping layer 202 are oxidized (e.g., further comprise oxygen). This may occur during the etching of the lower electrode layer 110. In some embodiments, the oxidization of the sidewalls of the upper electrode layer 114 and the capping layer 202 along the sidewalls of the upper electrode layer 114 and the capping layer 202 may occur during the etching of the lower electrode layer 110. In some embodiments, the width 1208 of oxidized portion 1110 and/or oxidized portion 1112 ranges from about 50 to about 150 angstroms, from about 75 to 150 angstroms, from about 100 to 150 angstroms, or some other width.

In some embodiments, the thickness of the lower electrode layer 110 is less than 75 angstroms, less than 50 angstroms, or some other thickness.

In some embodiments, a barrier layer 1202 is between conductive interconnect 104 and dielectric layer 102. In some embodiments, a barrier layer 1204 is between conductive interconnect and layers 122, 120, 116, 114. In some embodiments, barrier layer 1202 and/or barrier layer 1204 comprise tantalum, tantalum nitride, or some other suitable material.

In some cases, the width of the undercut (e.g., the lateral offset) of the lower electrode layer 110, the width of oxidized portions 1110, 1112, the thickness of layer 1104, and/or the width of portion 1106 can be determined using transmission electron microscopy (TEM) or some other suitable method. can be determined using transmission electron microscopy (TEM) or some other suitable method.

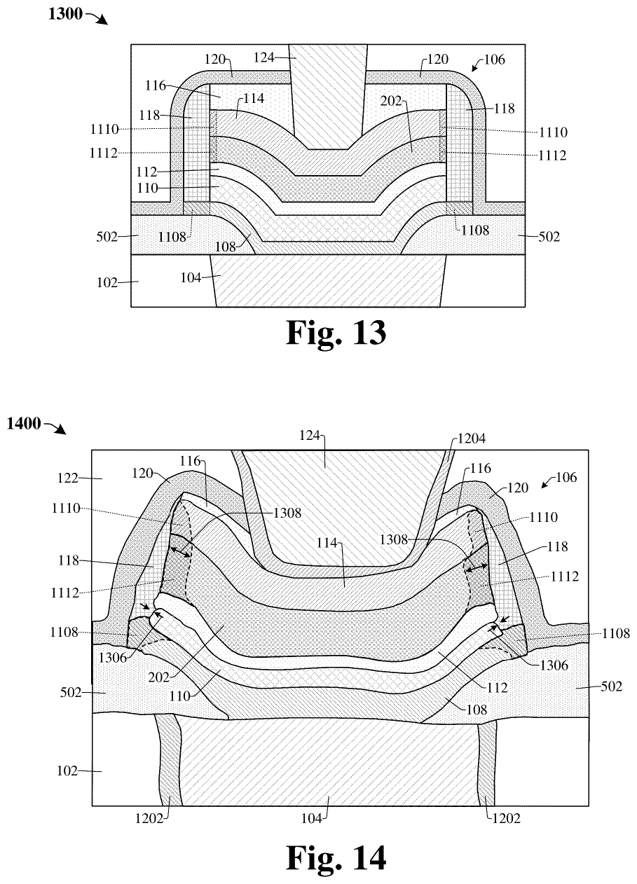

FIG. 13 and FIG. 14 illustrate cross-sectional views 1300, 1400, respectively, of some embodiments of the memory cell 106 in which the lower electrode layer 110 is substantially devoid of the “undercut” (e.g., the lateral recesses at 1102 of FIG. 11).

Thus, the sidewalls of the lower electrode layer 110 are substantially aligned with the sidewalls of the data storage layer 112, the sidewalls of the capping layer 202, the sidewalls of the upper electrode layer 114, and the sidewalls of the hard mask layer 116. For example, the sidewalls of the lower electrode layer 110 are laterally offset from the sidewalls of the data storage layer 112, the sidewalls of the capping layer 202, the sidewalls of the upper electrode layer 114, and the sidewalls of the hard mask layer 116 (e.g., width 1306) by about 1 angstrom to about 50 angstroms, less than 50 angstroms, less than 30 angstroms, less than 20 angstroms, less than 10 angstroms, less than 5 angstroms, or some other suitable value.

In some embodiments, the undercut of the lower electrode layer 110 can be reduced by reducing exposure of the lower electrode layer 110 to oxygen (e.g., reducing oxygen exposure time, reducing oxygen concentration during exposure, etc.) during the etching of the lower electrode layer 110, as described in more detail with reference to FIG. 19. In some embodiments, reducing the exposure of the lower electrode layer 110 to oxygen during the etching of the lower electrode layer 110 can also reduce the oxidization of the capping layer 202 and the upper electrode layer 114 (e.g., reduce the width of oxidized portion 1110 and oxidized portion 1112 of the capping layer 202). For example, the widths of portions 1110 and/or portion 1112 may be reduced by greater than 30%, by greater than 50%, by greater than 60%, or some other amount. In some embodiments, the width 1308 of oxidized portion 1110 and/or oxidized portion 1112 is less than about 100 angstroms, less than about 75 angstroms, less than about 50 angstroms, less than about 25 angstroms, less than about 5 angstroms, or some other width.

In some embodiments, the undercut of the lower electrode layer 110 can be reduced by increasing the thickness of the lower electrode layer 110 so that the thickness of the lower electrode layer 110 is substantially large. The thickness of the lower electrode layer 110 is greater than a thickness of the data storage layer 112. In some embodiments, the thickness of the lower electrode layer 110 is greater than or approximately equal to a thickness of the barrier layer 108. In some embodiments, the thickness of the lower electrode layer 110 is greater than 75 angstroms, greater than 90 angstroms, greater than 100 angstroms, ranges from about 75 angstroms to about 200 angstroms, ranges from about 100 angstroms to about 200 angstroms, or some other suitable thickness.

In some embodiments, reducing the undercut of the lower electrode layer 110 can prevent or reduce the deposition of lower electrode atoms on the data storage layer 112 (e.g., reduce or eliminate layer 1104 and reduce or eliminate portion 1106 of the data storage layer 112). In some embodiments, reducing the undercut of the lower electrode layer 110 can reduce the width of the edge portions 1108 of barrier layer 108 which comprise etchants.

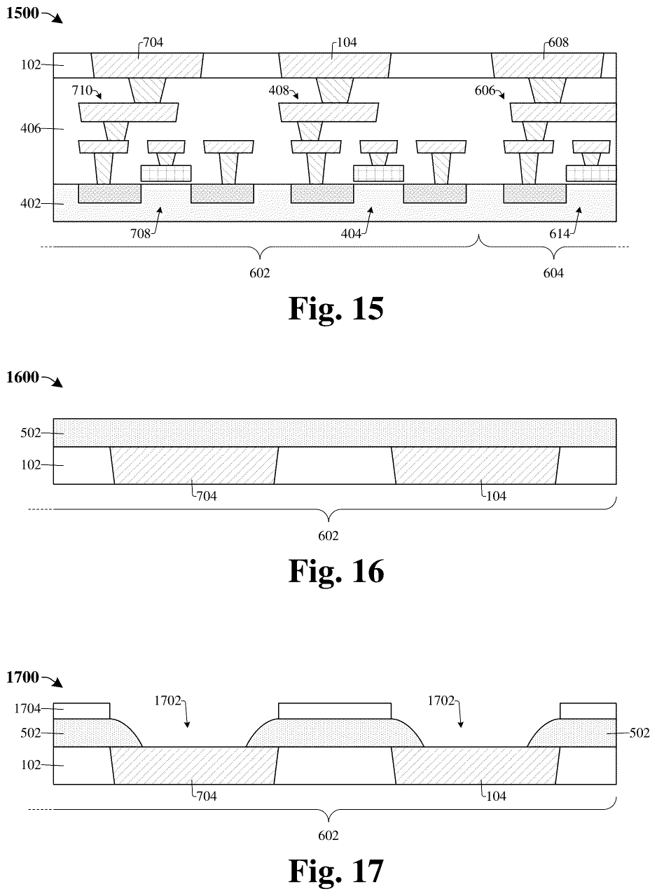

FIGS. 15-25 illustrate cross-sectional views 1500-2500 of some embodiments of a method of forming an integrated chip comprising a memory cell 106, the memory cell 106 comprising a spacer layer 118 covering sidewalls of an upper electrode layer 114, sidewalls of a data storage layer 112, and sidewalls of a lower electrode layer 110. Although FIGS. 15-25 are described in relation to a method, it will be appreciated that the structures disclosed in FIGS. 15-25 are not limited to such a method, but instead may stand alone as structures independent of the method.

As shown in cross-sectional view 1500 of FIG. 15, transistors are formed over and/or along a semiconductor substrate 402. For example, transistors 404, 708 are formed in a memory region 602 and transistor 614 is formed in a logic region 604. Further, dielectric layers are formed over the semiconductor substrate 402. For example, dielectric structure 406 and dielectric layer 102 are formed over the semiconductor substrate 402. Furthermore, conductive interconnects are formed over and coupled to the transistors. For example, interconnect structure 408 and conductive line 104 are formed over and coupled to transistor 404 in the memory region 602. Interconnect structure 710 and conductive line 704 are formed over and coupled to transistor 708 in the memory region 602. Interconnect structure 606 and conductive line 608 are formed over and coupled to transistor 614 in the logic region 604.

As shown in cross-sectional view 1600 of FIG. 16, a diffusion blocking dielectric layer 502 is deposited over dielectric layer 102 and conductive lines 104, 704. In some embodiments, the diffusion blocking dielectric layer 502 comprises silicon oxide, silicon carbide, silicon nitride, silicon oxycarbide, silicon oxynitride, silicon carbonitride, boron nitride, aluminum nitride, or some other suitable material and is deposited by a chemical vapor deposition (CVD) process, a physical vapor deposition (PVD) process, an atomic layer deposition (ALD) process, or some other suitable process.

As shown in cross-sectional view 1700 of FIG. 17, the diffusion blocking dielectric layer 502 is etched to form openings 1702 in the diffusion blocking dielectric layer 502 over the conductive lines in the memory region 602 (e.g., conductive lines 104, 704) to uncover portions of the conductive lines in the memory region 602. In some embodiments, sidewalls of the diffusion blocking dielectric layer 502 that form the openings 1702 are angled as a result of the etching.

In some embodiments, a masking layer 1704 is formed over the diffusion blocking dielectric layer 502 and the etching is performed according to the masking layer 1704. In some embodiments, the masking layer 1704 comprises photoresist, a hard mask material, or some other suitable material. The masking layer may be removed during and/or after the etching. In some embodiments, the etching comprises a dry etching process such as, for example, plasma etching process, a reactive ion etching process, an ion beam etching process, or some other suitable process.

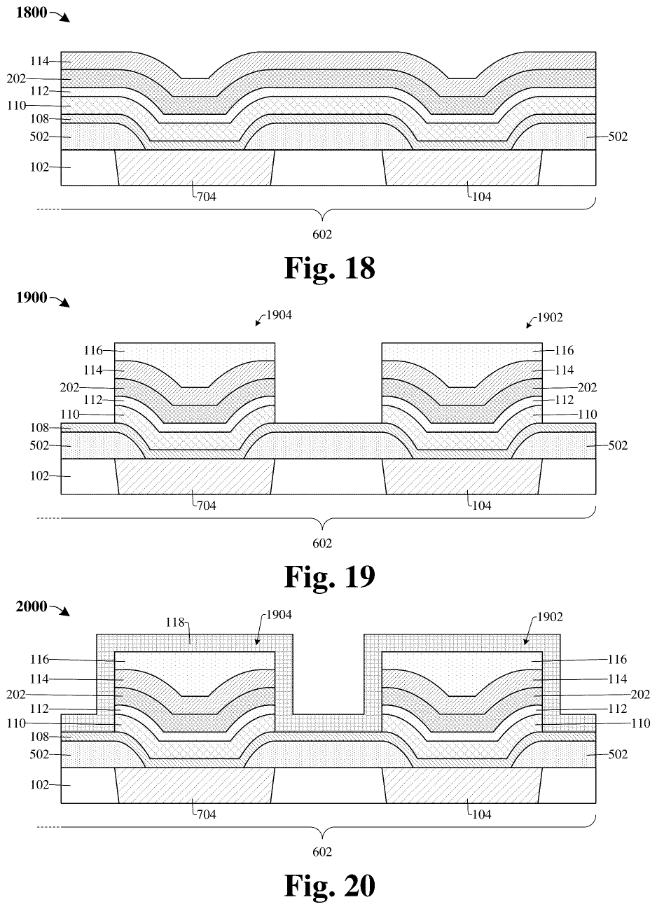

As shown in cross-sectional view 1800 of FIG. 18, a barrier layer 108 is conformally deposited on the diffusion blocking dielectric layer 502 and on the conductive lines in the memory region 602 (e.g., on conductive lines 104, 704). A lower electrode layer 110 is conformally deposited on the barrier layer 108. A data storage layer 112 is conformally deposited on the lower electrode layer 110. In some embodiments, a capping layer 202 is conformally deposited on the data storage layer 112. An upper electrode layer 114 is conformally deposited on the capping layer 202.

In some embodiments, the lower electrode layer 110 is deposited to have a substantially large thickness. Increasing the thickness of the lower electrode layer 110 may reduce the lateral recessing (e.g., “undercutting”) of the lower electrode layer 110 during the etching of the lower electrode layer 110, and may reduce the amount of lower electrode material (e.g., 1104, 1106 of FIG. 11) deposited on the data storage layer 112 during the etching of the lower electrode layer 110. Thus, a performance and/or a reliability of the memory cell can be improved. For example, the effective area of the memory cell can be increased, a bit error rate (BER) of the memory cell can be reduced, natural yield can be improved, repair rate can be improved, etc. The thickness of the lower electrode layer 110 is greater than a thickness of the data storage layer 112. In some embodiments, the thickness of the lower electrode layer 110 is greater than or approximately equal to a thickness of the barrier layer 108. In some embodiments, the thickness of the lower electrode layer 110 is greater than 75 angstroms, greater than 90 angstroms, greater than 100 angstroms, or some other thickness.

In some embodiments, the lower electrode layer 110 comprises ruthenium, rhodium, palladium, osmium, iridium, platinum, gold, silver, copper, aluminum, tungsten, tantalum, titanium, an alloy of any of ruthenium, rhodium, palladium, osmium, iridium, platinum, gold, silver, copper, aluminum, tungsten, tantalum, and titanium, a nitride of any of ruthenium, rhodium, palladium, osmium, iridium, platinum, gold, silver, copper, aluminum, tungsten, tantalum, and titanium, or some other suitable material and is deposited by a CVD process, a PVD process, an ALD process, or some other suitable process.

In some embodiments, the thickness of the barrier layer 108 ranges from about 5 angstroms to about 140 angstroms, from about 10 angstroms to about 100 angstroms, from about 25 angstroms to about 75 angstroms, or some other suitable range. In some embodiments, the barrier layer 108 comprises tantalum, titanium, ruthenium, aluminum, cobalt, molybdenum, rhodium, tantalum nitride, titanium nitride, ruthenium nitride, aluminum nitride, cobalt nitride, molybdenum nitride, rhodium nitride, tungsten nitride, manganese nitride, nickel nitride, tin nitride, magnesium nitride or some other suitable material and is deposited by a CVD process, a PVD process, an ALD process, or some other suitable process.

In some embodiments, the thickness of the data storage layer 112 ranges from about 10 angstroms to about 100 angstroms, from about 10 angstroms to about 90 angstroms, from about 10 angstroms to about 80 angstroms, or some other suitable range. In some embodiments, the data storage layer 112 comprises a high-k dielectric metal oxide such as, for example, hafnium oxide, zirconium oxide, lanthanum oxide, gadolinium oxide, yttrium oxide, aluminum oxide, some other high-k dielectric material, or some other suitable material and is deposited by a CVD process, a PVD process, an ALD process, or some other suitable process.

In some embodiments, the thickness of the capping layer 202 ranges from about 25 angstroms to about 200 angstroms, from about 50 angstroms to about 175 angstroms, from about 50 angstroms to about 150 angstroms, or some other suitable range. In some embodiments, the capping layer 202 comprises titanium, hafnium, platinum, aluminum, tantalum, zirconium, nickel, iridium, or some other suitable material and is deposited by a CVD process, a PVD process, an ALD process, or some other suitable process.

In some embodiments, the thickness of the upper electrode layer 114 ranges from about 20 angstroms to about 200 angstroms, from about 30 angstroms to about 170 angstroms, from about 50 angstroms to about 150 angstroms, or some other suitable range. In some embodiments, the upper electrode layer 114 comprises ruthenium, rhodium, palladium, osmium, iridium, platinum, gold, silver, copper, aluminum, tungsten, tantalum, titanium, an alloy of any of ruthenium, rhodium, palladium, osmium, iridium, platinum, gold, silver, copper, aluminum, tungsten, tantalum, and titanium, a nitride of any of ruthenium, rhodium, palladium, osmium, iridium, platinum, gold, silver, copper, aluminum, tungsten, tantalum, and titanium, or some other suitable material and is deposited by a CVD process, a PVD process, an ALD process, or some other suitable process.

As shown in cross-sectional view 1900 of FIG. 19, a hard mask layer 116 is deposited on the upper electrode layer 114 and the hard mask layer 116 is etched to form individual hard mask structures from the hard mask layer 116. The hard mask structures are directly over conductive lines 104, 704. In some embodiments, the hard mask layer 116 comprises silicon nitride, silicon oxynitride, silicon carbonitride, silicon oxycarbonitride, some metal nitride, or some other suitable material and is deposited by a CVD process, a PVD process, and ALD process, or some other suitable process. In some embodiments, a masking layer (not shown) is formed over the hard mask layer and the hard mask layer 116 is etched according to the masking layer. In some embodiments, the etching comprises a dry etching process or some other suitable process.

Next, the upper electrode layer 114, the capping layer 202, the data storage layer 112, and the lower electrode layer 110 are etched according to the patterned hard mask layer 116 (e.g., according to the individual hard mask structures that remain after etching the hard mask layer 116) to form layer stacks 1902, 1904 over conductive lines 104, 704. The etching stops at the barrier layer 108. In some embodiments, the etching comprises a plasma etching process or some other suitable process. A gas used during the etching comprises oxygen gas, a halogen (e.g., fluorine, chlorine, bromine, iodine) gas, a combination thereof, or some other suitable gas. In some embodiments, the etching includes an ashing process which uses oxygen plasma for cleaning after the etching.

In some embodiments, the upper electrode layer 114 and/or the capping layer 202 may be oxidized during the etching of the lower electrode layer 110. In some embodiments, the lower electrode layer 110 may be laterally recessed (e.g., undercut) during the etching of the lower electrode layer 110, and atoms removed from the lower electrode layer 110 during the etching of the lower electrode layer 110 may be deposited on the data storage layer 112 and/or may diffuse into the data storage layer 112.

The oxidation of the upper electrode layer 114, the oxidation of the capping layer 202, the undercut of the lower electrode layer 110, and/or the deposition of lower electrode material on the data storage layer 112 may be reduced by reducing the oxygen gas concentration, reducing the voltage used to generate plasma from the oxygen gas, and/or reducing the duration of the exposure of the oxygen gas to the lower electrode layer 110 during the etching of the lower electrode layer 110. For example, in some embodiments, the time that the lower electrode layer 110 is exposed to electrode etching gas (e.g., oxygen-containing gas) during the etching of the lower electrode layer 110 is less than the time that the barrier layer 108 is exposed to barrier etching gas (e.g., oxygen gas, halogen gas, a combination gas, or some other suitable etching gas) during the etching of the barrier layer 108. In some embodiments, the etching gas used during the etching of the lower electrode layer 110 comprises oxygen and a halogen, and the oxygen portion is reduced so that more than half (e.g., 50%) of the etching gas is halogen and less than half of the etching gas is oxygen. In some embodiments, the oxygen portion of the etching gas is reduced so that more than three quarters (e.g., 75%) of the etching gas is halogen and less than one quarter (e.g., 25%) of the etching gas is oxygen. In some embodiments, the voltage applied to generate the etching plasma during the etching of the lower electrode layer 110 is zero or some other suitable low voltage.

Further, reducing the ashing time or skipping the ashing process altogether may reduce the oxidization of layers 114, 202, reduce the undercut of the lower electrode layer 110, and to reduce or prevent the deposition of lower electrode atoms on the data storage layer 112. Thus, in some embodiments, the ashing process is skipped (e.g., the ashing time is zero). In some embodiments in which a short ashing process is performed, the voltage applied during the ashing of the lower electrode layer 110 is zero or some other suitable low voltage.

By reducing the oxidization of various layers of the memory cell and by reducing the undercutting of the lower electrode layer 110, a performance and/or a reliability of the memory cell can be improved. For example, the effective area of the memory cell 106 can be increased, a forming voltage (e.g., the voltage for writing the memory cell) can be reduced, a bit error rate can be reduced, a set/reset shot count (e.g., the number of voltage pulses applied to set/reset the memory cell) can be reduced, a set/reset shot count stability can be improved, a set/reset speed can be improved, a natural yield (e.g., amount of memory cells that function properly without repair) can improved, a repair rate (e.g., amount of memory cells that function properly after repair) can be improved, and/or structural integrity of the memory cell 106 may be improved.

In some embodiments, atoms of the etching gas may diffuse into exposed portions of the barrier layer 108 during the etching. Thus, in some embodiments, the exposed portions of the barrier layer 108 may further include oxygen, fluorine, chlorine, bromine, iodine, or the like. In some embodiments, the exposed portions of the barrier layer 108 may be increased thickness as a result of the etching gas diffusion.

In some embodiments, the etching of the upper electrode layer 114 and/or the etching of the capping layer 202 use low-oxygen or oxygen-free etching processes to further reduce oxidization of the upper electrode layer 114 and/or the capping layer 202.

As shown in cross-sectional view 2000 of FIG. 20, a spacer layer 118 is conformally deposited on the layer stacks 1902, 1904 and the barrier layer 108. The spacer layer 118 covers sidewalls of the hard mask layer 116, sidewalls of the upper electrode layer 114, sidewalls of the capping layer 202, sidewalls of the data storage layer 112, sidewalls of the lower electrode layer 110, and upper surfaces of the barrier layer 108.

In some embodiments, the spacer layer 118 comprises an oxygen-free dielectric material. For example, in some embodiments, the spacer layer 118 comprises silicon nitride, silicon carbide, silicon carbonitride, or some other suitable material. In some embodiments, the spacer layer 118 comprises a substantially low-oxygen dielectric material in which the atomic percentage of oxygen is less than 20%, less than 15%, less than 10%, or some other suitable value. For example, in some embodiments, the spacer layer 118 comprises silicon oxynitride, silicon oxycarbide, silicon oxycarbonitride, or some other suitable material having a low atomic percentage of oxygen. Forming the spacer layer 118 of an oxygen-free or low-oxygen dielectric material may help reduce oxidization of the layers on which the spacer layer 118 is deposited.

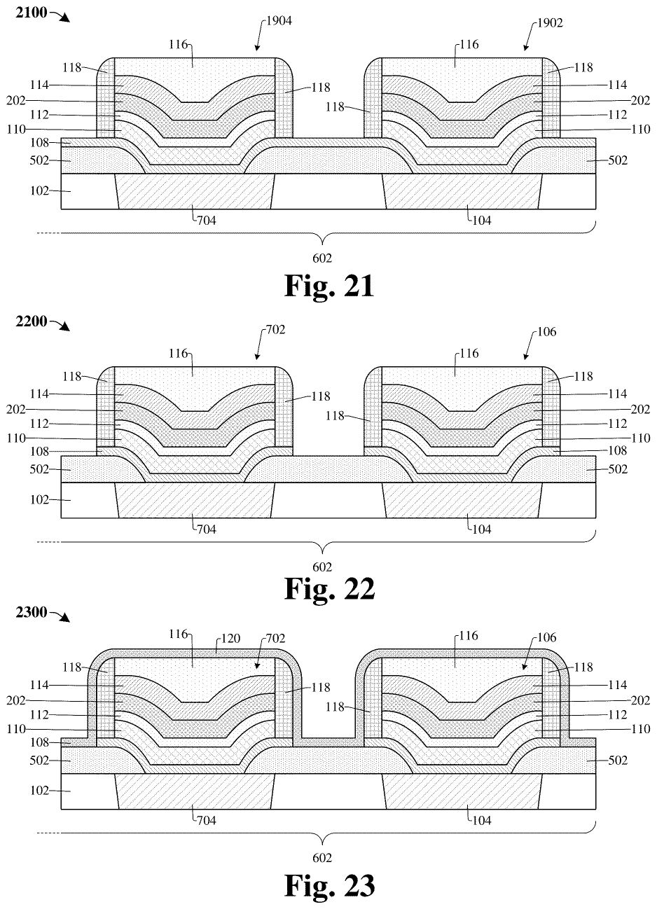

As shown in cross-sectional view 2100 of FIG. 21, the spacer layer 118 is etched to remove the spacer layer 118 from upper surfaces of the hard mask layer 116 and from portions of the barrier layer 108, thus forming spacer structures on sidewalls of each of the layer stacks 1902, 1904 from the spacer layer 118. For example, a first spacer structure covers sidewalls of layer stack 1902 and a second spacer structure covers sidewalls of layer stack 1904.

In some embodiments, the etching comprises a dry etching process or some other suitable process. In some embodiments, the etching is performed without forming a masking layer over the spacer layer 118 (e.g., the etching is a blanket etching process). In some embodiments, the etching may remove small portions of the hard mask layer 116 and/or the barrier layer 108.

As shown in cross-sectional view 2200 of FIG. 22, the barrier layer 108 is etched according to the layer stacks 1902, 1904 (e.g., according to hard mask layer 116) and the spacer layer 118 to separate the barrier layer 108 into individual barrier structures corresponding to individual memory cells. For example, the etching forms individual memory cells 106, 702 from the layer stacks 1902, 1904 and the barrier layer 108.

In some embodiments, the etching comprises a dry etching process or some other suitable process. The etching stops at the diffusion blocking dielectric layer 502. For example, the etching has a high selectivity to the barrier layer 108 versus the diffusion blocking dielectric layer 502 (e.g., the barrier layer 108 has a substantially higher etch rate than the diffusion blocking dielectric layer 502). In some embodiments, the etching may remove small portions of the diffusion blocking dielectric layer 502. Because the etching has little effect on the diffusion blocking dielectric layer 502, the thickness of the diffusion blocking dielectric layer 502 may not be substantially affected and thus the diffusion blocking capability of the diffusion blocking dielectric layer 502 may not be substantially reduced.

The spacer layer 118 protects the lower electrode layer 110, the data storage layer 112, the capping layer 202, and the upper electrode layer 114 during the etching of the barrier layer 108. Thus, an oxidization of the lower electrode layer 110, the capping layer 202, and/or the upper electrode layer 114 during the etching of the barrier layer 108 can be reduced. As a result, a performance and/or a reliability of the memory cells can be further improved.

As shown in cross-sectional view 2300 of FIG. 23 an encapsulation layer 120 is conformally deposited over the memory cells 106, 702 and the diffusion blocking dielectric layer 502 to encapsulate the memory cells 106, 702. In some embodiments, the encapsulation layer 120 comprises silicon dioxide or some other suitable material formed by a CVD process using a tetraethyl orthosilicate (TEOS) and oxygen. In some embodiments, an oxygen-containing gas is used in a cleaning process before the deposition of the encapsulation layer 120.

The spacer layer 118 protects the lower electrode layer 110, the data storage layer 112, the capping layer 202, and the upper electrode layer 114 during the cleaning process and the deposition of the encapsulation layer 120. Thus, an oxidization of the lower electrode layer 110, the capping layer 202, and/or the upper electrode layer 114 can be further reduced. As a result, a performance and/or a reliability of the memory cells can be further improved.

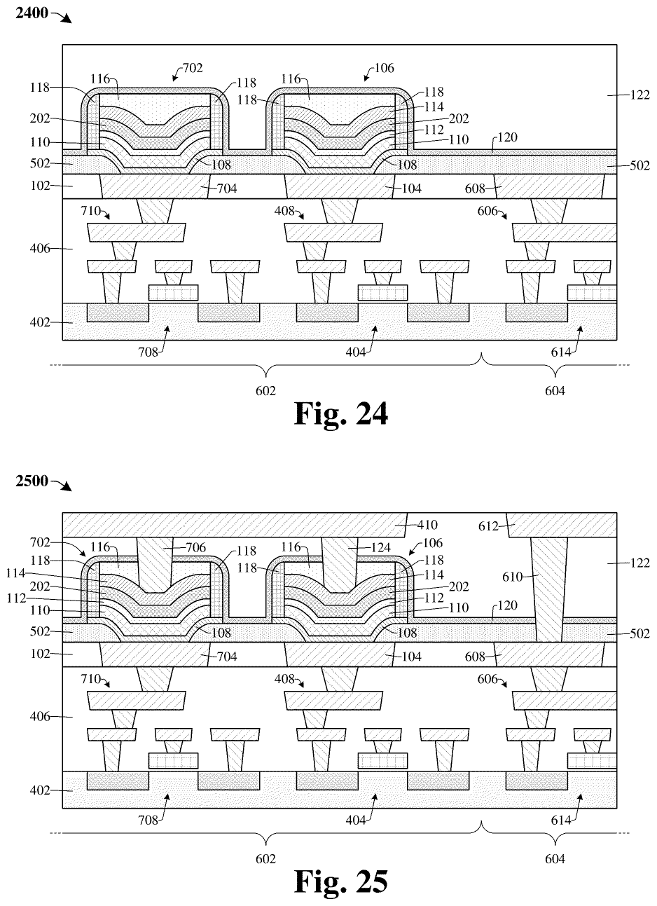

As shown in cross-sectional view 2400 of FIG. 24, a dielectric layer 122 is deposited over the encapsulation layer 120. In some embodiments, the dielectric layer comprises a low-k dielectric material, an extremely low-k dielectric material (e.g., having a dielectric constant k of less than 2.5), or some other suitable material and is deposited by a CVD process, a PVD process, and ALD process, or some other suitable process.

As shown in cross-sectional view 2500 of FIG. 25, conductive interconnects are formed over and coupled to the memory cells in the memory region 602. For example, conductive via 124 and conductive via 706 are formed over and coupled to memory cells 106, 702. Further, in some embodiments, conductive line 410 is formed over and coupled to conductive vias 124, 706. In addition, conductive interconnects are formed in the logic region 604. For example, conductive via 610 is formed over and coupled to conductive line 608, and conductive line 612 is formed over and coupled to conductive via 610.

In some embodiments, the conductive interconnects are formed by etching dielectric layer 122, encapsulation layer 120, hard mask layer 116 (for conductive vias 124, 706), and the diffusion blocking dielectric layer 502 (for conductive via 610) with one or more etching processes to form openings therein, and depositing one or more conductive materials (e.g., copper, aluminum, tungsten, titanium, tantalum, etc.) in the openings with one or more deposition processes.

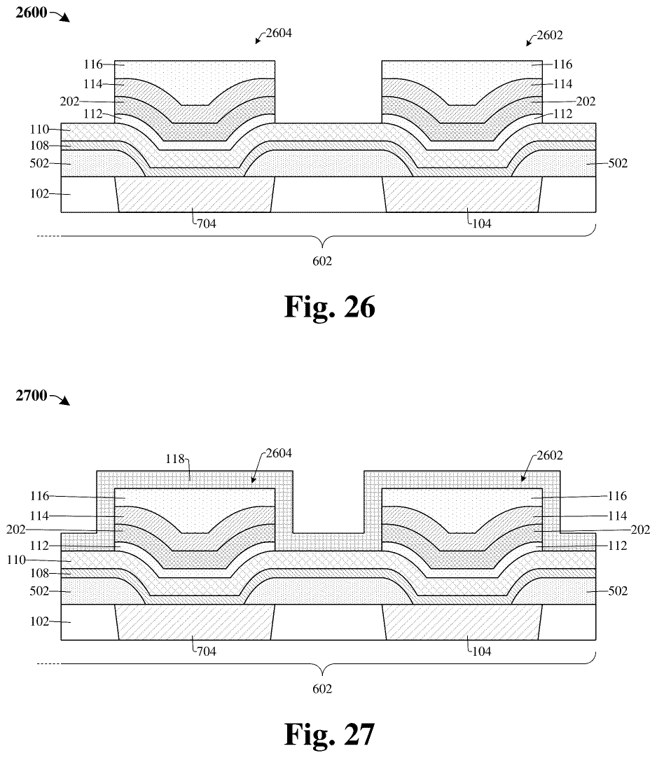

FIGS. 26-30 illustrate cross-sectional views 2600-3000 of some embodiments of a method of forming a memory cell 106 in which the lower electrode layer 110 is between the spacer layer 118 and the barrier layer 108. Although FIGS. 26-30 are described in relation to a method, it will be appreciated that the structures disclosed in FIGS. 26-30 are not limited to such a method, but instead may stand alone as structures independent of the method.

As shown in cross-sectional view 2600 of FIG. 26, following the deposition of layers 108, 110, 112, 202, 114 and the formation of individual hard mask structures from the hard mask layer 116, the upper electrode layer 114, the capping layer 202, and the data storage layer 112 are etched according to the patterned hard mask layer 116 to form layer stacks 2602, 2604. The etching stops at the lower electrode layer 110.

As shown in cross-sectional view 2700 of FIG. 27, the spacer layer 118 is conformally deposited on layer stacks 2602, 2604 (e.g., on the hard mask layer 116, the upper electrode layer 114, the capping layer 202, and the data storage layer 112) and the lower electrode layer 110. The spacer layer 118 covers sidewalls of the hard mask layer 116, sidewalls of the upper electrode layer 114, sidewalls of the capping layer 202, sidewalls of the data storage layer 112, and upper surfaces of the lower electrode layer 110.

As shown in cross-sectional view 2800 of FIG. 28, the spacer layer 118 is etched to remove the spacer layer 118 from upper surfaces of the hard mask layer 116 and from portions of the lower electrode layer 110, thus forming spacer structures on sidewalls the layer stacks 2602, 2604 (e.g., on sidewalls of the data storage layer 112, sidewalls of the capping layer 202, and sidewalls of the upper electrode layer 114).

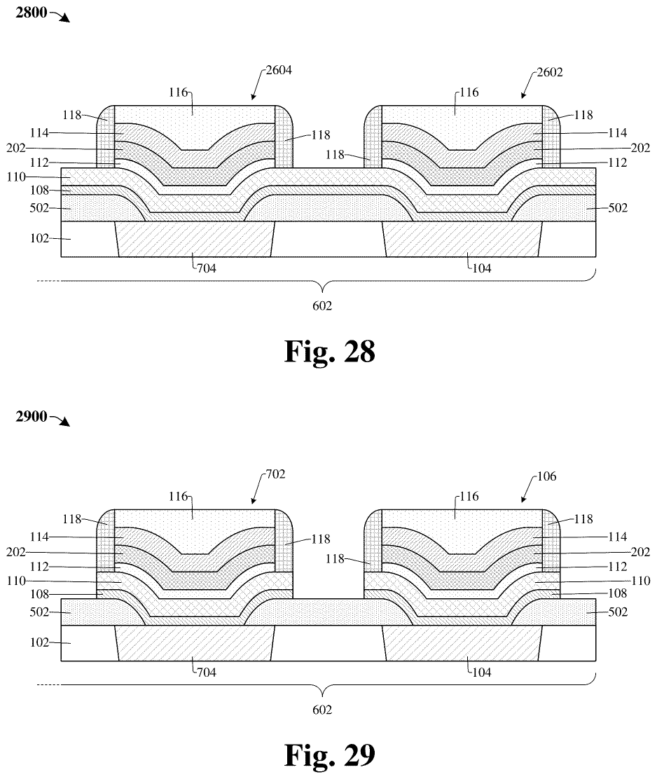

As shown in cross-sectional view 2900 of FIG. 29, the lower electrode layer 110 and the barrier layer 108 are etched according to the hard mask layer 116 and the spacer layer 118 to separate the lower electrode layer 110 into individual lower electrodes and to separate the barrier layer 108 into individual barrier structures. The etching forms memory cells 106, 702 from the layer stacks 2602, 2604 and etched layers 110, 108.

The spacer layer 118 protects the sidewalls of the upper electrode layer 114, the capping layer 202, and the data storage layer 112 during the etching of the lower electrode layer 110. As a result, oxidization of the protected layers can be reduced and thus a performance and/or reliability of the memory cells can be improved.

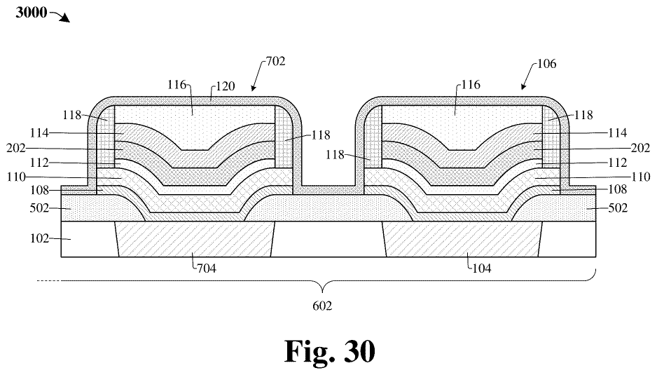

As shown in cross-sectional view 3000 of FIG. 30, the encapsulation layer 120 is conformally deposited over the memory cells 106, 702 and the diffusion blocking dielectric layer 502 to encapsulate the memory cells 106, 702.

The spacer layer 118 protects the sidewalls of the upper electrode layer 114, the capping layer 202, and the data storage layer 112 during the deposition of the encapsulation layer 120. As a result, oxidization of the protected layers can be further reduced and thus a performance and/or reliability of the memory cells can be further improved.

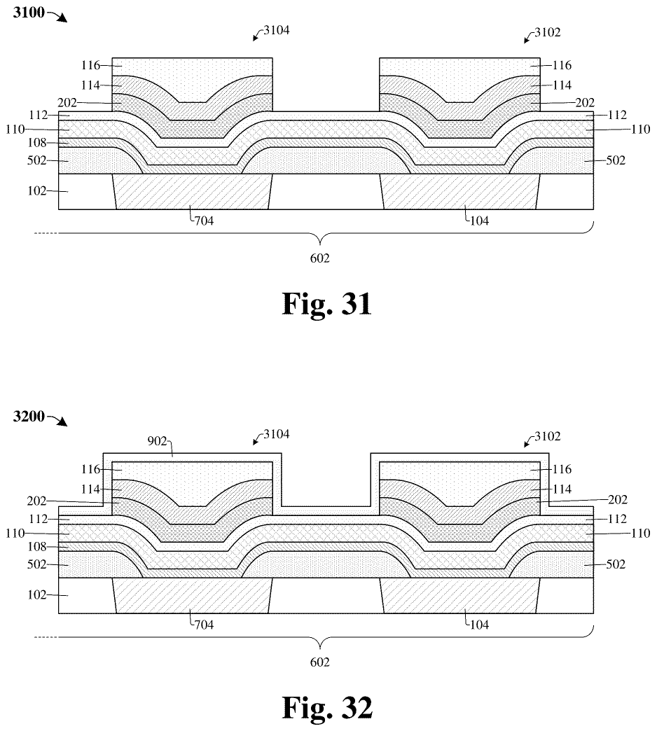

FIGS. 31-38 illustrate cross-sectional views 3100-3800 of some embodiments of a method of forming a memory cell 106 in which two spacer layers protect the layers of the memory cell 106. Although FIGS. 31-38 are described in relation to a method, it will be appreciated that the structures disclosed in FIGS. 31-38 are not limited to such a method, but instead may stand alone as structures independent of the method.

As shown in cross-sectional view 3100 of FIG. 31, following the deposition of layers 108, 110, 112, 202, 114, and the formation of individual hard mask structures from the hard mask layer 116, the upper electrode layer 114 and the capping layer 202 are etched according to the patterned hard mask layer 116 to form layer stacks 3102, 3104. In some embodiments, the etching stops at the data storage layer 112. In some other embodiments, the data storage layer 112 is etched and the etching stops at the lower electrode layer 110 (see, for example, FIG. 10).

As shown in cross-sectional view 3200 of FIG. 32, a first spacer layer 902 is conformally deposited on the layer stacks 3102, 3104 (e.g., on the hard mask layer 116, the upper electrode layer 114, and the capping layer 202). The first spacer layer 902 covers sidewalls of the hard mask layer 116, sidewalls of the upper electrode layer 114, sidewalls of the capping layer 202, and upper surfaces of the data storage layer 112.

In some embodiments, the spacer layer 118 comprises a low-oxygen dielectric material or an oxygen-free dielectric material and is deposited by a CVD process, a PVD process, and ALD process, or some other suitable process.

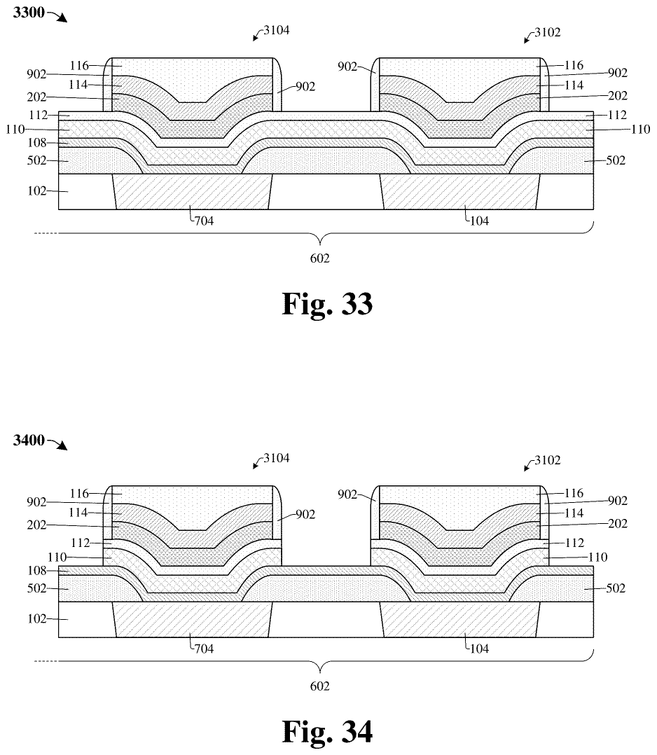

As shown in cross-sectional view 3300 of FIG. 33, the first spacer layer 902 is etched to remove the first spacer layer 902 from upper surfaces of the hard mask layer 116 and from portions of the data storage layer 112, thus forming first spacer structures on sidewalls of the layer stacks 3102, 3104 (e.g., on sidewalls of the upper electrode layer 114 and sidewalls of the capping layer 202).

In some embodiments, the etching comprises a dry etching process or some other suitable process. In some embodiments, the etching is performed without forming a masking layer over the spacer layer 118 (e.g., the etching is a blanket etching process). In some embodiments, the etching may remove small portions of the hard mask layer 116 and/or the data storage layer 112.

Although FIGS. 31-33 illustrate the first spacer layer 902 being formed by depositing the first spacer layer on the upper electrode layer 114 and the capping layer 202 after etching the upper electrode layer 114 and the capping layer 202, in some other embodiments, the first spacer layer 902 is gradually formed during the etching of the upper electrode layer 114 and the etching of the capping layer 202 by performing a cyclical deposition-etching process.

As shown in cross-sectional view 3400 of FIG. 34, the data storage layer 112, the lower electrode layer 110, and the barrier layer 108 are etched according to the hard mask layer 116 and the spacer layer 118 to separate the data storage layer 112 into individual data storage structures and to separate the lower electrode layer 110 into individual lower electrodes. The data storage structures and the lower electrodes further form the layer stacks 3102, 3104.

The first spacer layer 902 protects the sidewalls of the upper electrode layer 114 and the sidewalls of the capping layer 202 during the etching of the data storage layer 112 and the lower electrode layer 110. As a result, oxidization of the protected layers can be reduced and thus a performance and/or reliability of the memory cells can be improved.

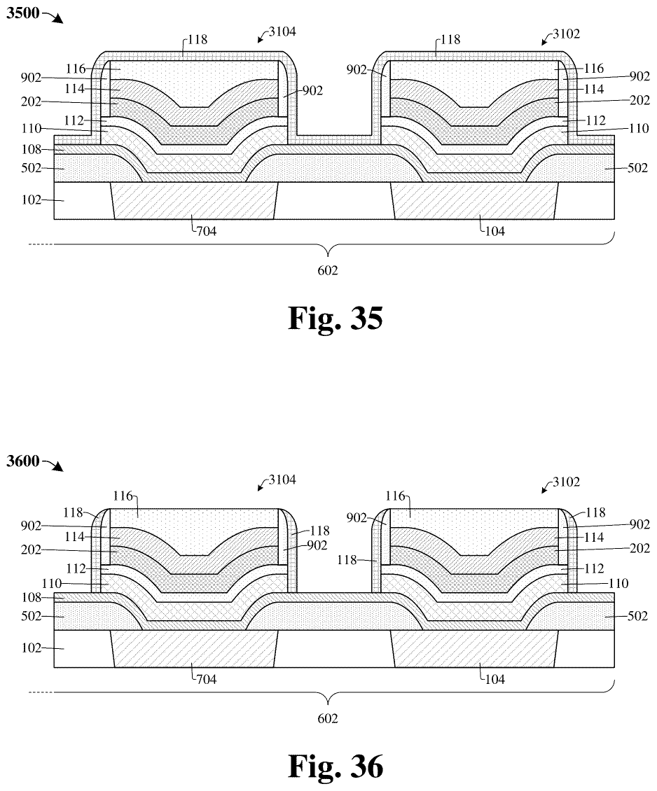

As shown in cross-sectional view 3500 of FIG. 35, a second spacer layer 118 is conformally deposited on the hard mask layer 116, the first spacer layer 902, the data storage layer 112, the lower electrode layer 110, and the barrier layer 108. The second spacer layer 118 covers sidewalls of the first spacer layer 902, sidewalls of the data storage layer 112, sidewalls of the lower electrode layer 110, and upper surfaces of the barrier layer 108.

In some embodiments, the second spacer layer 118 comprises a low-oxygen dielectric material or an oxygen-free dielectric material to reduce oxidization of the layers on which the second spacer layer 118 is deposited.

As shown in cross-sectional view 3600 of FIG. 36, the second spacer layer 118 is etched to remove the second spacer layer 118 from upper surfaces of the hard mask layer 116 and from portions of the barrier layer 108, thus forming second spacer structures on sidewalls of the first spacer layer 902, sidewalls of the data storage layer 112, and sidewalls of the lower electrode layer 110.

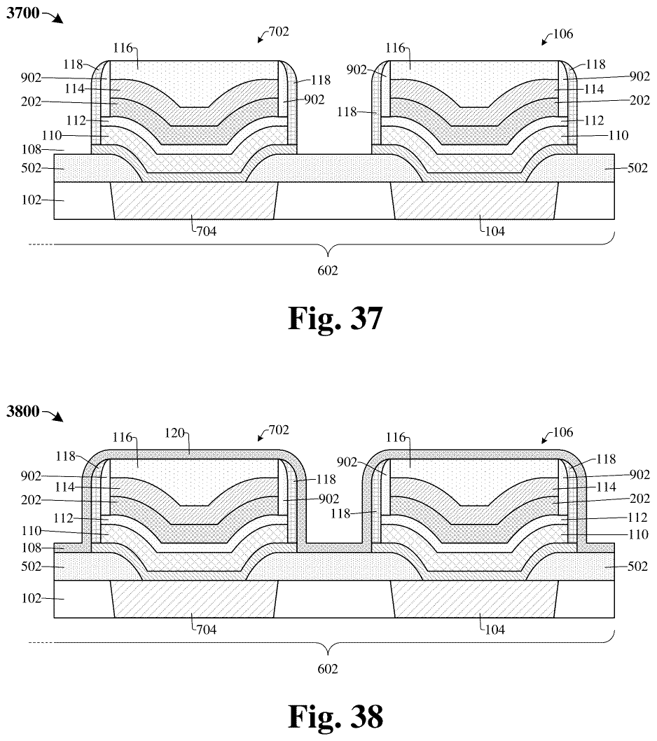

As shown in cross-sectional view 3700 of FIG. 37, the barrier layer 108 is etched according to the hard mask layer 116 and the spacer layer 118 to separate the barrier layer 108 into individual barrier structures. The etching further forms memory cells 106, 702.

The second spacer layer 118 protects the sidewalls of the data storage layer 112 and the sidewalls of the lower electrode layer 110 during the etching of barrier layer 108.

As shown in cross-sectional view 3800 of FIG. 38, the encapsulation layer 120 is conformally deposited over the memory cells 106, 702 and the diffusion blocking dielectric layer 502 to encapsulate the memory cells 106, 702.

The second spacer layer 118 protects the sidewalls of the data storage layer 112 and the sidewalls of the lower electrode layer 110 during the deposition of the encapsulation layer 120.

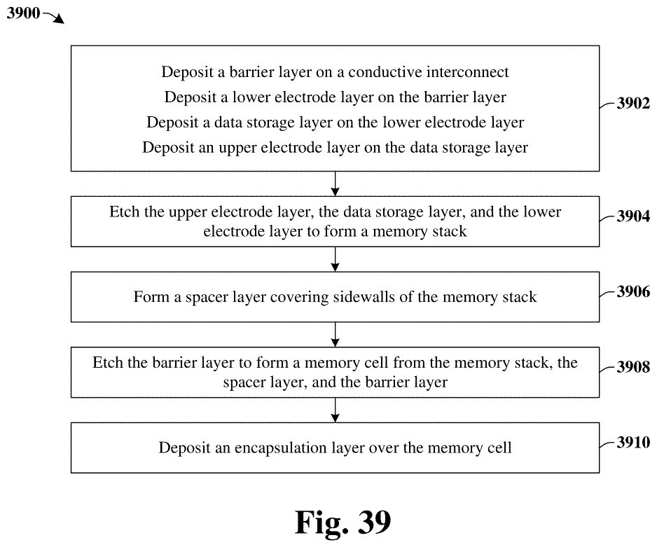

FIG. 39 illustrates a flow diagram of some embodiments of a method 3900 of forming an integrated chip comprising a memory cell, the memory cell comprising a spacer layer covering sidewalls of an upper electrode layer, sidewalls of a data storage layer, and sidewalls of a lower electrode layer. While method 3900 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At block 3902, deposit a barrier layer on a conductive interconnect, deposit a lower electrode layer on the barrier layer, deposit a data storage layer on the lower electrode layer, and deposit an upper electrode layer on the data storage layer. The lower electrode layer is deposited with a substantially large thickness to reduce undercutting of the lower electrode layer during subsequent etching of the lower electrode layer. FIG. 18 illustrates a cross-sectional view 1800 of some embodiments corresponding to block 3902.

At block 3904, etch the upper electrode layer, the data storage layer, and the lower electrode layer to form a memory stack. The oxygen gas exposure (e.g., the oxygen gas concentration, the oxygen exposure time, the voltage applied during the oxygen gas exposure, etc.) during the etching of the lower electrode layer is reduced to reduce oxidation of the upper electrode layer and reduce undercutting of the lower electrode layer. Further, a post-etching ashing process time is reduced or eliminated and a voltage applied during ashing is reduced or zero to further reduce oxidation of the upper electrode layer and further reduce undercutting of the lower electrode layer. FIG. 19 illustrates a cross-sectional view 1900 of some embodiments corresponding to block 3904.

At block 3906, form a spacer layer covering sidewalls of the memory stack. For example, the spacer layer is deposited on sidewalls of the upper electrode layer, sidewalls of the data storage layer, and sidewalls of the lower electrode layer. Next, the spacer layer is etched to delimit the spacer layer. FIGS. 20-21 illustrate cross-sectional views 2000-2100 of some embodiments corresponding to block 3906.

At block 3908, etch the barrier layer to form a memory cell from the memory stack, the spacer layer, and the barrier layer. FIG. 22 illustrates a cross-sectional view 2200 of some embodiments corresponding to block 3908.

At block 3910, deposit an encapsulation layer over the memory cell. The spacer layer protects the sidewalls of the upper electrode layer and the sidewalls of the lower electrode layer from oxidation during the deposition of the encapsulation layer. FIG. 23 illustrates a cross-sectional view 2300 of some embodiments corresponding to block 3910.

Thus, the present disclosure relates to an integrated chip and a method of forming the integrated chip, the integrated chip comprising a memory cell and one or more spacer layers on sidewalls of the memory cell to protect the memory cell during processing.

Accordingly, in some embodiments, the present disclosure relates to an integrated chip. The integrated chip includes a barrier layer including a first conductive material over a semiconductor substrate. The integrated chip includes a lower electrode layer including a second conductive material, different than the first conductive material, over the barrier layer. The integrated chip includes a dielectric layer over the lower electrode layer. The integrated chip includes an upper electrode layer over the dielectric layer. The integrated chip includes an encapsulation layer including a first dielectric material encapsulating the upper electrode layer, the dielectric layer, the lower electrode layer, and the barrier layer. The integrated chip includes a spacer layer including a second dielectric material, different than the first dielectric material, on an upper surface of the barrier layer. The encapsulation layer is spaced from sidewalls of the lower electrode layer, sidewalls of the dielectric layer, and sidewalls of the upper electrode layer by the spacer layer. In some embodiments, the spacer layer contacts the upper surface of the barrier layer, the sidewalls of the lower electrode layer, and the sidewalls of the dielectric layer. In some embodiments, the spacer layer is a first spacer layer. In some embodiments, the integrated chip further includes a second spacer layer on an upper surface of the dielectric layer. In some embodiments, the second spacer layer covers the sidewalls of the upper electrode layer, and the first spacer layer covers the sidewalls of the lower electrode layer, the sidewalls of the dielectric layer, and sidewalls of the second spacer layer. In some embodiments, a thickness of the lower electrode layer is greater than a thickness of the dielectric layer and greater than a thickness of the barrier layer. In some embodiments, the spacer layer is substantially devoid of oxygen. In some embodiments, the second dielectric material includes oxygen, the first dielectric material is silicon dioxide, and an atomic percentage of the oxygen in the second dielectric material is less than an atomic percentage of the oxygen in the silicon dioxide of the first dielectric material. In some embodiments, the sidewalls of the lower electrode layer, the sidewalls of the dielectric layer, and the sidewalls of the upper electrode layer are substantially aligned. In some embodiments, the sidewalls of the lower electrode layer are laterally offset from the sidewalls of the dielectric layer and the sidewalls of the upper electrode layer by 1 angstrom to 50 angstroms. In some embodiments, the integrated chip further includes a transistor over the semiconductor substrate, a first conductive interconnect coupled to a first source/drain of the transistor, a capping layer between the dielectric layer and the upper electrode layer, and a hard mask layer over the upper electrode layer. The barrier layer is on an upper surface of the first conductive interconnect. The capping layer includes a third conductive material. The upper electrode layer includes a fourth conductive material different than the third conductive material. The encapsulation layer encapsulates the capping layer and the hard mask layer. The encapsulation layer is spaced from sidewalls of the capping layer and sidewalls of the hard mask layer by the spacer layer.

In other embodiments, the present disclosure relates to a method for forming an integrated chip. The method includes depositing a barrier layer including a first conductive material over a semiconductor substrate. The method includes depositing a lower electrode layer including a second conductive material, different than the first conductive material, over the barrier layer. The method includes depositing a data storage layer over the lower electrode layer. The method includes depositing an upper electrode layer over the data storage layer. The method includes etching the upper electrode layer, the data storage layer, and the lower electrode layer. The method includes depositing a spacer layer including a first dielectric material on an upper surface of the barrier layer, along sidewalls of the lower electrode layer, along sidewalls the data storage layer, along sidewalls of the upper electrode layer, and over the upper electrode layer. The method includes etching the spacer layer to remove the spacer layer from over the upper electrode layer. The method includes etching the barrier layer according to the spacer layer. The method includes depositing an encapsulation layer including a second dielectric material, different than the first dielectric material, over the upper electrode layer, along sidewalls of the spacer layer, and along sidewalls of the barrier layer. The spacer layer covers the sidewalls of the upper electrode layer, the sidewalls of the data storage layer, and the sidewalls of the lower electrode layer during the depositing of the encapsulation layer. In some embodiments, a duration that the lower electrode layer is exposed to a first etching gas during the etching of the lower electrode layer is shorter than a duration that the barrier layer is exposed to a second etching gas during the etching of the barrier layer. In some embodiments, an etching gas used during the etching of the lower electrode layer comprises oxygen and a halogen, the halogen constitutes more than half of the etching gas, and the oxygen constitutes less than half of the etching gas. In some embodiments, the sidewalls of the upper electrode layer are oxidized after the etching of the lower electrode layer, and a width of an oxidized region of the lower electrode layer is less than 100 angstroms. In some embodiments, the sidewalls of the lower electrode layer are laterally offset from the sidewalls of the data storage layer and the sidewalls of the upper electrode layer after the etching of the lower electrode layer, and the offset is less than 50 angstroms. In some embodiments, tetraethyl orthosilicate (TEOS) and oxygen are used in the depositing of the encapsulation layer. In some embodiments, the method further includes forming a hard mask layer over the upper electrode layer. In some embodiments, the upper electrode layer, the data storage layer, and the lower electrode layer are etched according to the hard mask layer. In some embodiments, the spacer layer is deposited along sidewalls of the hard mask layer and over an upper surface of the hard mask layer. In some embodiments, etching the spacer layer removes the spacer layer from over the hard mask layer. In some embodiments, the barrier layer is etched according to the spacer layer and the hard mask layer. In some embodiments, the encapsulation layer is deposited over the upper surface of the hard mask layer. In some embodiments, the spacer layer is a first spacer layer. In some embodiments, the method further includes depositing a second spacer layer on an upper surface of the data storage layer, on sidewalls of the upper electrode layer, and over the upper electrode layer. In some embodiments, the method further includes etching the second spacer layer to remove the spacer layer from over the upper electrode layer. In some embodiments, the data storage layer and the lower electrode layer are etched after the etching of the second spacer layer. In some embodiments, the first spacer layer is deposited over the second spacer layer and on sidewalls of the second spacer layer after the etching of the data storage layer and the lower electrode layer. In some embodiments, a central portion of the barrier layer comprises the first conductive material, edge portions of the barrier layer comprise the first conductive material and one or more of oxygen, fluorine, chlorine, bromine, and iodine after the etching of the lower electrode layer, and the spacer layer contacts the barrier layer at the edge portions of the barrier layer. In some embodiments, the edge portions of the barrier layer have a greater thickness than the central portion of the barrier layer. In some embodiments, a portion of the second conductive material is on the sidewalls of the data storage layer after the etching of the lower electrode layer.

In yet other embodiments, the present disclosure relates to a method for forming an integrated chip, the method includes forming a barrier layer including a first conductive material over a semiconductor substrate. The method includes forming a lower electrode layer including a second conductive material, different than the first conductive material, over the barrier layer. The method includes forming a dielectric layer over the lower electrode layer. The method includes forming an upper electrode layer over the dielectric layer. The method includes forming a spacer layer including a first dielectric material on an upper surface of the barrier layer. The method includes encapsulating the upper electrode layer, the dielectric layer, the lower electrode layer, the barrier layer, and the spacer layer with an encapsulation layer including a second dielectric material different than the first dielectric material. The encapsulation layer is spaced from sidewalls of the lower electrode layer, sidewalls of the dielectric layer, and sidewalls of the upper electrode layer by the spacer layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated chip comprising:
a barrier layer comprising a first conductive material over a semiconductor substrate;
a lower electrode layer comprising a second conductive material, different than the first conductive material, over the barrier layer;
a dielectric layer over the lower electrode layer;
an upper electrode layer over the dielectric layer;
an encapsulation layer comprising a first dielectric material encapsulating the upper electrode layer, the dielectric layer, the lower electrode layer, and the barrier layer; and
a spacer layer comprising a second dielectric material, different than the first dielectric material, on an upper surface of the barrier layer, wherein the encapsulation layer is spaced from sidewalls of the lower electrode layer, sidewalls of the dielectric layer, and sidewalls of the upper electrode layer by the spacer layer.

2. The integrated chip of claim 1, wherein the spacer layer contacts the upper surface of the barrier layer, the sidewalls of the lower electrode layer, and the sidewalls of the dielectric layer.

3. The integrated chip of claim 1, wherein the spacer layer is a first spacer layer, the integrated chip further comprising:
a second spacer layer on an upper surface of the dielectric layer, wherein the second spacer layer covers the sidewalls of the upper electrode layer, wherein the first spacer layer covers the sidewalls of the lower electrode layer, the sidewalls of the dielectric layer, and sidewalls of the second spacer layer.

4. The integrated chip of claim 1, wherein a thickness of the lower electrode layer is greater than a thickness of the dielectric layer and greater than a thickness of the barrier layer.

5. The integrated chip of claim 1, the spacer layer is substantially devoid of oxygen.

6. The integrated chip of claim 1, wherein the second dielectric material comprises oxygen, wherein the first dielectric material is silicon dioxide, and wherein an atomic percentage of the oxygen in the second dielectric material is less than an atomic percentage of the oxygen in the silicon dioxide of the first dielectric material.

7. The integrated chip of claim 1, wherein the sidewalls of the lower electrode layer, the sidewalls of the dielectric layer, and the sidewalls of the upper electrode layer are substantially aligned.

8. The integrated chip of claim 1, wherein the sidewalls of the lower electrode layer are laterally offset from the sidewalls of the dielectric layer and the sidewalls of the upper electrode layer by 1 angstrom to 50 angstroms.

9. The integrated chip of claim 1, further comprising:
a transistor over the semiconductor substrate;
a first conductive interconnect coupled to a first source/drain of the transistor, wherein the barrier layer is on an upper surface of the first conductive interconnect;
a capping layer between the dielectric layer and the upper electrode layer, wherein the capping layer comprises a third conductive material and the upper electrode layer comprises a fourth conductive material different than the third conductive material; and
a hard mask layer over the upper electrode layer,
wherein the encapsulation layer further encapsulates the capping layer and the hard mask layer, and wherein the encapsulation layer is spaced from sidewalls of the capping layer and sidewalls of the hard mask layer by the spacer layer.

10. A method for forming an integrated chip, the method comprising:
depositing a barrier layer comprising a first conductive material over a semiconductor substrate;
depositing a lower electrode layer comprising a second conductive material, different than the first conductive material, over the barrier layer;
depositing a data storage layer over the lower electrode layer;
depositing an upper electrode layer over the data storage layer;
etching the upper electrode layer, the data storage layer, and the lower electrode layer;
depositing a spacer layer comprising a first dielectric material on an upper surface of the barrier layer, along sidewalls of the lower electrode layer, along sidewalls the data storage layer, along sidewalls of the upper electrode layer, and over the upper electrode layer;
etching the spacer layer to remove the spacer layer from over the upper electrode layer;
etching the barrier layer according to the spacer layer; and
depositing an encapsulation layer comprising a second dielectric material, different than the first dielectric material, over the upper electrode layer, along sidewalls of the spacer layer, and along sidewalls of the barrier layer, wherein the spacer layer covers the sidewalls of the upper electrode layer, the sidewalls of the data storage layer, and the sidewalls of the lower electrode layer during the depositing of the encapsulation layer.

11. The method of claim 10, wherein a duration that the lower electrode layer is exposed to a first etching gas during the etching of the lower electrode layer is shorter than a duration that the barrier layer is exposed to a second etching gas during the etching of the barrier layer.

12. The method of claim 10, wherein an etching gas used during the etching of the lower electrode layer comprises oxygen and a halogen, and wherein the halogen constitutes more than half of the etching gas and the oxygen constitutes less than half of the etching gas.

13. The method of claim 10, wherein the sidewalls of the upper electrode layer are oxidized after the etching of the lower electrode layer, and wherein a width of an oxidized region of the lower electrode layer is less than 100 angstroms.

14. The method of claim 10, wherein the sidewalls of the lower electrode layer are laterally offset from the sidewalls of the data storage layer and the sidewalls of the upper electrode layer after the etching of the lower electrode layer, and wherein the offset is less than 50 angstroms.

15. The method of claim 10, further comprising:
forming a hard mask layer over the upper electrode layer, wherein the upper electrode layer, the data storage layer, and the lower electrode layer are etched according to the hard mask layer, wherein the spacer layer is deposited along sidewalls of the hard mask layer and over an upper surface of the hard mask layer, wherein etching the spacer layer removes the spacer layer from over the hard mask layer, wherein the barrier layer is etched according to the spacer layer and the hard mask layer, and wherein the encapsulation layer is deposited over the upper surface of the hard mask layer.

16. The method of claim 10, wherein the spacer layer is a first spacer layer, the method further comprising:
depositing a second spacer layer on an upper surface of the data storage layer, on sidewalls of the upper electrode layer, and over the upper electrode layer; and
etching the second spacer layer to remove the spacer layer from over the upper electrode layer,
wherein the data storage layer and the lower electrode layer are etched after the etching of the second spacer layer, and wherein the first spacer layer is deposited over the second spacer layer and on sidewalls of the second spacer layer after the etching of the data storage layer and the lower electrode layer.

17. The method of claim 10, wherein a central portion of the barrier layer comprises the first conductive material, and wherein edge portions of the barrier layer comprise the first conductive material and one or more of oxygen, fluorine, chlorine, bromine, and iodine after the etching of the lower electrode layer, wherein the spacer layer contacts the barrier layer at the edge portions of the barrier layer.

18. The method of claim 17, wherein the edge portions of the barrier layer have a greater thickness than the central portion of the barrier layer.

19. The method of claim 10, wherein a portion of the second conductive material is on the sidewalls of the data storage layer after the etching of the lower electrode layer.

20. A method for forming an integrated chip, the method comprising:
forming a barrier layer comprising a first conductive material over a semiconductor substrate;
forming a lower electrode layer comprising a second conductive material, different than the first conductive material, over the barrier layer;
forming a dielectric layer over the lower electrode layer;
forming an upper electrode layer over the dielectric layer;
forming a spacer layer comprising a first dielectric material on an upper surface of the barrier layer; and
encapsulating the upper electrode layer, the dielectric layer, the lower electrode layer, the barrier layer, and the spacer layer with an encapsulation layer comprising a second dielectric material different than the first dielectric material, wherein the encapsulation layer is spaced from sidewalls of the lower electrode layer, sidewalls of the dielectric layer, and sidewalls of the upper electrode layer by the spacer layer.
